(19) United States
(12) Patent Application Publication
(10) Pub. No.: US 2006/0290783 A1
(43) Pub. Date: Dec. 28, 2006

(54) Method for selecting a video test signal

(76) Inventors: Shinobu Kubota, Fujisawa (JP); Kazuhiko Tanaka, Urayasu (JP)

Correspondence Address: MATTHEW D. RABDAU;TEKTRONIX, INC., 14150 S.W. KARL BRAUN DRIVE, P.O. BOX 500 (50-LAW), BEAVERTON, OR, 97077-0001, US

(21) Appl. No.: 11/472,875

(22) Filed: Jun. 21, 2006

(30) Foreign Application Priority Data
Jun. 22, 2005 (JP) 2005-181889

(51) Int. Cl. G01R 29/26; H04N 17/00

(52) U.S. Cl. 348/181; 348/189; 702/69

(57) ABSTRACT

A user can select an output desired video test signal of a desired video format for a video test signal generator by fewer operations. There are two modes; format priority mode and test signal priority mode. If the user starts the video test signal selection, lists of video test signals and/or video formats are displayed on a display screen. If the user selects a video test signal name on the screen, the process enters into the test signal priority mode and a list of video formats that have the selected test signal is displayed. The user can select a desired video format to determine the output video test signal of the desired video format. At this time, the user may change the video format as many times as needed without changing the selected video test signal. If the user wants to select another video test signal of the selected video format, the user selects the desired video format possibly in combination with a control key on an interface of the generator and then the process jumps to the format priority mode. In the format priority mode, a list of video test signals having the selected video format is displayed. The user can select a desired video test signal to decide the output video test signal of the selected video format. If the user again wants to select another video format of the selected test signal, the user selects the desired video test signal possibly in combination with the control key and then the process again jumps to the test signal priority mode.

### BACKGROUND

Embodiments of the present invention relate generally to video test signal selection, and more particularly to video test signal selection for a video test signal generator that can provide a plurality of video test signals of multi-video formats.

A display unit, such as CRT, or LCD, is used for displaying pictures, or video sequences, for TV broadcasting, displaying using a computer, such as a personal computer (PC) or both. A plurality of video test signals has been used for testing the display unit and/or a display circuit to confirm it works well. A video test signal generator provides the video test signals used by manufactures of TV sets and PCs, and used by a broadcasting station.

There are many video formats for TV broadcasting and PC. For example, representative formats for standard definition television (SDTV) are NTSC, PAL and SECAM and there are many formats depending on different frame rates, pixel numbers, etc. for high definition television (HDTV). There are video formats for PCs, such as VGA, SVGA, XGA, etc. and they are slightly different depending on the manufactures.

There are many kinds of video test signals, such as color bar, multi-burst, etc. U.S. Pat. No. 4,635,096 discloses an apparatus for generating such various video test signals.

FIG. 1 is a functional block diagram of such a video test signal generator 26. CPU 30, memory 32, DAC (digital to analog converter) 34 are on a bus 28. The CPU 30 controls operation of the generator 26. The memory 32 may be hard disk drive, RAM, or other suitable storage means, and may store video test signal data, along with a program that the generator 26 processes. The DAC 34 converts the video test signal data into analog video test signals. In addition, a user interface 40 including operating means 36 and display 38 is coupled to the bus 28. The operation means 36 may have rotary knob, operation keys, pointing device (mouse, etc.) and is used for selecting displayed items, inputting numeric value into the generator 26 and setting various modes with cooperating with the display unit 38.

Now, a video test signal generator can generate a plurality of video test signals in multiple video formats, which makes it complicate for a user to select a desired video test signal.

FIG. 2 is a flow chart of a conventional video test signal selection procedure. A user conducts a predetermined operation to starts a process for selecting a video test signal (step 12). A video test signal generator displays a list or table of available video formats (step 14) on the display unit and the user selects a desired video format from the list (step 16). Then the video test signal generator displays a list or table of available video test signals that the selected video format has (step 18) and the user selects a desired video test signal from the list (step 20). If the user wants to change the test signal again, as indicated by “Yes” in a step 22, the process returns to the step 20, which allows the user to select another test signal without changing the video format. If the user wants to change the video format, as indicated by “Yes” in a step 24, the process returns to the step 14 and the above steps are conducted again.

If a 100% color bar signal of the NTSC format is displayed at the present and the user wants the generator to output a 100% color bar signal of the PAL format next time, that is, the same test signal of a different video format, the conventional selection method as shown in FIG. 2 requires the user to return to the step 14 and reselect a video format first and also reselect a 100% color bar signal from a displayed list of a plurality of the video test signals.

### SUMMARY

Accordingly, the ability to select a desired video test signal of a desired video format from a plurality of video test signals having a plurality of multiple video formats is provided.

Embodiments of the present relate to video test signal selection for a video test signal generator that can output a plurality of video test signals in multiple video formats. The present invention provides two processes to select a desired video test signal; in one a video format is selected first and then a video test signal is selected, and in the other a video test signal is selected at first and then a video format is selected. A user can use whichever mode the user prefers, which may lead to fewer operations to select the desired video test signal of the desired video format.

The first process may be referred as a format priority mode. After the video format is selected, video test signals that the selected video format has are displayed on an interface of the video test signal generator, and the user selects the desired video test signal from them to select a desired video test signal of the selected video format. The second process may be referred as a test signal priority mode. After a video test signal is selected, video formats that have the selected video test signal are displayed on the interface, and the user can select a desired video format from them to select a desired selected video format of the video test signal.

In the format priority mode, if a button or icon on a display screen corresponding to a desired video format is selected for example by pressing a predetermined key on the interface then a list of video test signals that the selected video format has is displayed. Similarly, in the test signal priority mode, if a button or icon on a display screen corresponding to a desired video test signal is selected then a list of video format signals that have the selected video test signal is displayed.

The objects, advantages and other novel features of embodiments of the present invention are apparent from the following detailed description when read in conjunction with the appended claims and attached drawings.

### BRIEF DESCRIPTION OF THE DRAWINGS

FIG. 1 is a functional block diagram of a video test signal generator.

FIG. 2 (prior art) is a flow chart of conventional procedures for selecting a video test signal output from a video test signal generator.

FIG. 3 is a flow chart for selecting a video test signal output from a video test signal generator according to the present invention.

FIG. 4 is a state diagram according to the present invention.

### DETAILED DESCRIPTION

Embodiments of the present invention provide two priority modes, or a test signal priority mode and a format priority mode to set a video test signal for output into a video test signal generator. In the test signal priority mode, a desired video test signal of a desired video format is selected by selecting the video test signal at first and then the video format. In the format priority mode, a desired video test signal of a desired video format is selected by selecting the video format at first and then the video test signal. A user may use one of the two modes to select the desired video test signal of the desired video format as the user likes. The two modes lead to fewer operations than before.

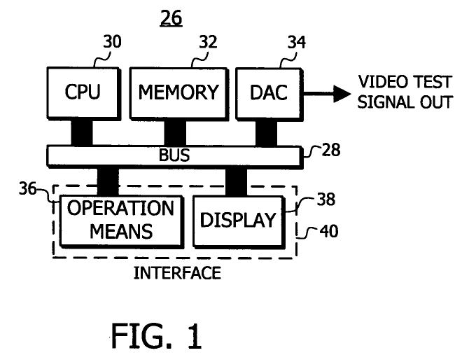

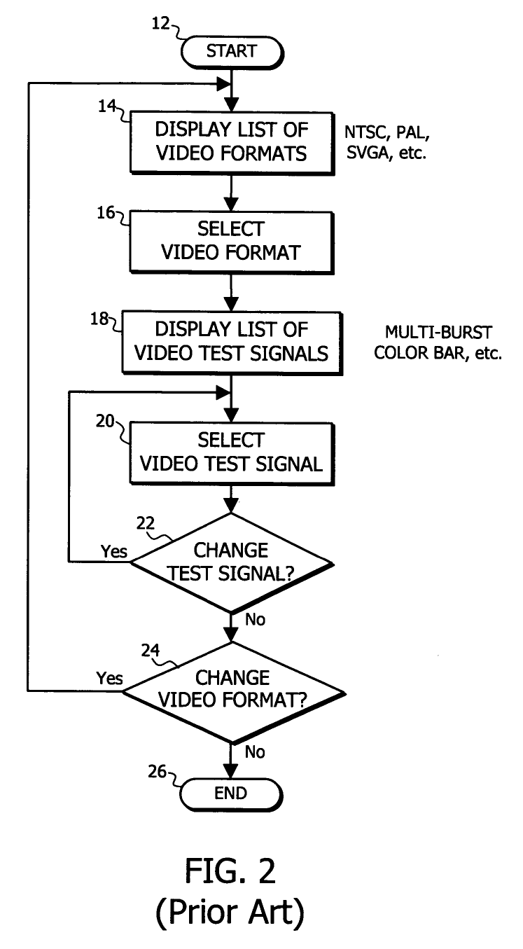

Embodiments of the present invention may be realized by the same hardware as the video test signal generator 26 shown in FIG. 1. Then the functional blocks in FIG. 1 are referred in the following description. But program for controlling the generator 26 features additional functions according to embodiments of the present invention.

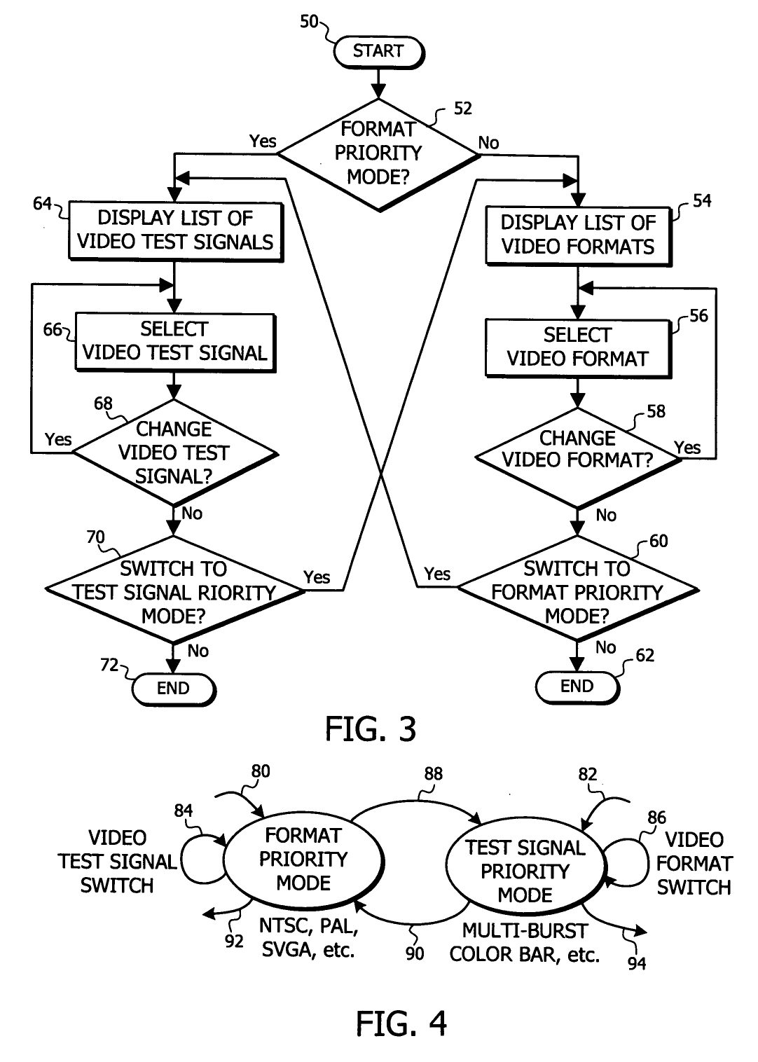

Referring to FIG. 3, the operations for selecting a video test signal start by conducting a predetermined operation using the interface 40 (step 50). An example of the predetermined operation may be pressing (or selecting) a button of a video format or test signal standard name displayed on a screen of the display 38 with pressing a control key on the interface 40, for example “CTRL”. Wherein the operation using the Ctrl key is described as a control key operation hereinafter. If the video format is selected, a step 52 becomes “Yes” and the process enters into the format priority mode and moves on to a step 64. Similarly, if the video test signal is selected, the step 52 becomes “No” and the process enters into the test signal priority mode and moves on to a step 54. The process following the step 54 is described below.

If the button of the video test signal standard name displayed on the screen of the display 38 is pressed or selected as described above, a list or table of video formats that have the selected video test signal standard is displayed on the screen (step 54). A user selects a desired video format from the list (step 56). The screen still displays the list and the user can change the selected format as many times as needed, which process corresponds to return to the step 56 because of “Yes” in a step 58. Then the desired video format is selected. Wherein if the user wants to select another video test signal of the selected video format, the process can jump to the step 64 by an operation of entering into the format priority mode, for example using the control key operation (step 60). If both the format and test signal are desired ones the selection operation of the video test signal ends (step 62). If the selection has finished, the user can conduct a signal output operation of the selected video test signal when necessary.

If the process moves on to the step 64 from the step 52 or the step 60, that is, a video format standard name button displayed on the screen is selected, for example, a list of video test signals that the selected video format has is displayed on the screen. The user can select a desired test signal from the list (step 66). The screen still displays the list and the user can change the selected video test signal as many times as needed, which process corresponds to return to the step 66 because of “Yes” in a step 68. Then the desired video test signal is selected. Wherein if the user wants to select another video format of the selected video test signal, the process can jump to the step 54 by the operation of entering into the test signal priority mode, for example using the control key operation. If both the format and test signal are desired ones the selection operation of the video test signal ends (step 72). If the selection has finished, the user can conduct a signal output operation of the selected video test signal when necessary.

A mode selection control may be implemented as a state machine, either in hardware, or in software running on the CPU 30. The mode selection control responds to the control key operation, for example. Referring to FIG. 4, embodiments of the present invention can enter into either mode at first as shown by arrows 80 and 82. In the format priority mode, one of the test signals of a previously selected video format can be selected as many times as needed as shown by an arrow 84. Similarly, in the test signal priority mode, one of the video formats that have a previously selected video test signal can be selected as many times as needed as shown by an arrow 86. The format priority mode and the test signal priority mode can be switched freely as needed as shown by arrows 88 and 90 by, for example, using the control key operation. If the selection has finished, it can escape from the modes as shown by arrows 92 and 94 to output the actual video test signal.

As described, embodiments of the present invention use a convenient mode of the format priority and the test signal priority modes and then a desired video test signal of a desired video format can be selected by fewer operations than before. Therefore, a display unit that can display many video signals, such as TV formats including NTSC, PAL, SECAM, HDTV, etc. and PC formats that may be different from manufacture to manufacture, can be tested using multiple test signal, or multiple formats, by repeatedly selecting test signals, formats, or both, in an efficient manner.

Although the embodiments of the invention have been disclosed, those skilled in the art will appreciate that modifications and improvements may be made without departing from the scope of the invention. For example, the control key operation may be done by “Ctrl,” “Alt,” “Shift” keys, or a combination of those control keys. Alternatively, other suitable keystroke or keystrock combination may be used. Furthermore, in other alternative embodiments, a mouse click, or a combination of mouse clicks, or a combination of a mouse click and a keyboard key, may be used to select the mode. The means of selection should not be limited to the possible means described here. The displayed buttons or icons corresponding to the video test signals or video formats may be prepared as hardware buttons or icons on the video test signal generator. The video test signal generator may be implemented using specialized hardware, or a combination of general purpose hardware and specialized hardware. Alternatively, in some cases embodiments of the video signal generator may be implemented as software designed to run on a general purpose computer, such as a PC.

It will be obvious to those having skill in the art that many additional changes may be made to the details of the above-described embodiments of this invention without departing from the underlying principles thereof. The scope of the present invention should, therefore, be determined only by the following claims.

What is claimed is:

1. A method for selecting an output video test signal of a video test signal generator that can provide a plurality of video test signals in multiple video formats comprising:
selecting a video test signal; and
subsequently selecting a video format to determine the output video test signal in the video format.

2. The method as recited in claim 1, wherein when a video test signal is selected, video formats that have the selected video test signal are displayed on a display of the video test signal generator.

3. The method as recited in claim 2, wherein the video formats are displayed as a list or icons on the display.

4. A video test signal generator that can provide a plurality of video test signals in multiple video formats comprising:
a format priority mode, in which a video format is selected and then a video test signal is selected to decide the output video test signal of the video format;
a test signal priority mode, in which a video test signal is selected and then a video format is selected to decide the output video test signal of the video format; and
a mode selection control to enable switching between the format priority mode and the test signal priority mode.

5. The video test signal generator as recited in claim 4, wherein when a video format is selected in the format priority mode, video test signals that the selected video format has are displayed on a display of the video test signal generator.

6. The video test signal generator as recited in claim 5, wherein when a video test signal is selected by a predetermined operation, the mode switch control causes the process to jump to the test signal priority mode.

7. The video test signal generator as recited in claim 6, wherein the predetermined operation is a press of a control key.

8. The video test signal generator as recited in claim 5, wherein the video test signals are displayed as a list or icons on the display.

9. The video test signal generator as recited in claim 4, wherein when a video test signal is selected in the test signal priority mode, video formats that have the selected video test signal are displayed on a display of the video test signal generator.

10. The video test signal generator as recited in claim 9, wherein when a video format is selected with a predetermined operation, the mode switch control causes the process jumps to the format priority mode.

11. The video test signal generator as recited in claim 10, wherein the predetermined operation is a press of a control key.

12. The video test signal generator as recited in claim 9, wherein the video formats are displayed as a list or icons on the display.

13. A method for selecting an output video test signal of a video test signal generator that can provide a plurality of video test signals in multiple video formats comprising:
selecting a format priority mode;
within the format priority mode, selecting a video format, and then selecting a video test signal to determine the output video test signal of the video format; and
selecting a test signal priority mode;
within the test signal priority mode, selecting the test signal, and then selecting the video format to determine the output video test signal of the video format.

14. The method of claim 13, further comprising when the video format is selected in the format priority mode, displaying video test signals that the selected video format has available on a display of the video test signal generator.

15. The method of claim 14, wherein selecting the test signal priority mode is accomplished by selecting a video test signal in combination with a predetermined operation.

16. The method of claim 15, wherein the predetermined operation comprises pressing a control key.

17. The method of claim 14, wherein the video test signals are displayed as a list or as icons on the display.

18. The method of claim 13, further comprising when the video test signal is selected in the test signal priority mode, displaying video formats that the selected video test signal has available on a display of the video test signal generator.

19. The method of claim 18, wherein selecting the format priority mode is accomplished by selecting a video format in combination with a predetermined operation.
